(19) United States
(12) Patent Application Publication
(10) Pub. No.: US 2002/0105265 A1
(43) Pub. Date: Aug. 8, 2002

(54) Organic electroluminescent device and method of making same

(76) Inventor: Feng-Ju Chuang, Hsin Chu (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 10/109,707

(22) Filed: Apr. 1, 2002

Related U.S. Application Data
(62) Division of application No. 09/531,413, filed on Mar. 20, 2000.

(51) Int. Cl. H05B 33/14

(52) U.S. Cl. 313/506

(57) ABSTRACT

A method for making an organic electroluminescent device comprises the steps of: f; forming a plurality of trenches penetrating into the substrate; forming an expected light emitting region between two adjacent trenches; forming a first electrode, an organic layer and a second electrode on each expected light emitting region; and forming an insulating passivation layer covering the resulting structure. The bottom of the trench is lower than the bottom of the first electrode on the expected light emitting region. Therefore, the trench provides sufficient isolation. The manufacturing method does not involve an interlayer insulating film, the second electrode and the organic layer can be precisely formed to simply processing and increase the effective light-emitting area.

### BACKGROUND OF THE INVENTION

(1) Field of the Invention

This invention relates to an organic electroluminescent device and method of making same, and more specifically the organic film and the second electrode can be precisely formed, and the effective light emitting area is increased.

(2) Background of the Invention

The display devices have found versatile application such as television, computer peripheral, advertising billboard, image telephone, or global positioning system (GPS). Of the various display devices, the organic electroluminescent (EL) devices have received much attention because the particular advantages of wide viewing angle, better displaying quality, compact display thickness, low power consumption, long duration and full-spectrum color display.

FIG. 1 is a sectional view of a conventional EL device. As shown in this figure, the EL device comprises a substrate 11, a first electrode 12 formed on the substrate 11, an organic layer 13 including at least one organic emitting layer (not shown) and a second 14 both formed on a predetermined location on the first electrode 12. The organic layer 13 may have the problem of deterioration caused by moisture or oxygen in the air, as a result, the light emitting area is decreased. Therefore, a protecting film 15 made from resin is coated over the whole surface of the EL device. However, the resin can not attached on the surface of the EL device for a long term. Moreover, the protecting film 15 may not be formed in a vacuum state, the deterioration caused by moisture or oxygen is still probable to occur.

The U. S. Pat. No. 5,457,357 “Organic electroluminescent device having improved durability and producing method” is disclosed to overcome about aforesaid problems. A polyimide layer is formed on the substrate and the first electrode. An organic layer and a second electrode are evaporated obliquely in one direction, and a metal film is formed in a vacuum state to have excellent adhesion to the EL device. However, the above-mentioned patent still has the following problems.

1. The EL device with RGB primal colors is not achievable, i.e., the EL device in this patent can not provide full-spectrum color;

2. The organic layer and the second electrode can not be precisely registered because they are evaporated obliquely in one direction. The pattern is not fine ; and

3. The organic layer and the second electrode are evaporated obliquely such that the end of the second electrode (apart from the polyimide layer) may have deviation. The problem of short circuit is probably to occur.

U.S. Pat. No. 5,701,055 with title “Organic electoluminescent display panel and method for manufacturing the same” also discloses an EL display device. As shown in FIGS. 2A to 2G, the manufacturing process thereof comprises the steps of: forming a first electrode 22 on a substrate 21 as shown in FIG. 2A; forming an electrical insulation rampart layer 28 on the first electrode 22 as shown in FIG. 2B; forming a plurality of contact windows on predetermined positions of the electrical insulation rampart layer 28 by mask 27 and lithography process as shown in FIG. 2C; forming a plurality of insulating layers 25 with convex portion by wet etching or dry etching the electrical insulation rampart layer 28 as shown in FIG. 2D, forming a plurality of organic layer 23 each emitting red, green or blue light, respectively between two insulating layers 25 by using a shadow mask 29 and oblique evaporation as shown in FIG. 2E; forming a second electrode 24 such that the organic layer 23 emits full-color light when being applied voltage as shown in FIG. 2F; forming an insulating sealing layer 26 to cover the device as shown in FIG. 2G.

However, the above-mentioned method still has the following problems even though the pattern is fine and full-color is provided:

1. Non-emitting region 255 exists below the insulating layers 25. The non-emitting region 255 does not illuminate and only the expected emitting region 235 contributes to the illuminance. The emitting efficiency is degraded especially the front light;

2. The process for forming insulating layers 25 is cumbersome ; and

3. The organic layer and the second electrode are formed by oblique evaporation, the problem of short circuit still remains.

It is the object of the present invention to provide an organic electroluminescent device and method of making same, whereby the process is simplified, the pattern is fine without short circuit problem and the effective light-emitting area is increased.

In one aspect of the present invention, a plurality of trenches are formed on the predetermined locations of the substrate to replace the conventional interlayer insulating film for isolation, whereby the process is simplified and full-color emission is possible.

In another aspect of the present invention, the second electrode and the organic layers are formed by vertical evaporation, the pattern is fine without short circuit problem.

In still another aspect of the present invention, another expected light-emitting region is formed in each trench, whereby the effective light-emitting area is increased.

The various objects and advantages of the present invention will be more readily understood from the following detailed description when read in conjunction with the appended drawing, in which:

### BRIEF DESCRIPTION OF DRAWING

FIG. 1 is a sectional view of a conventional EL device

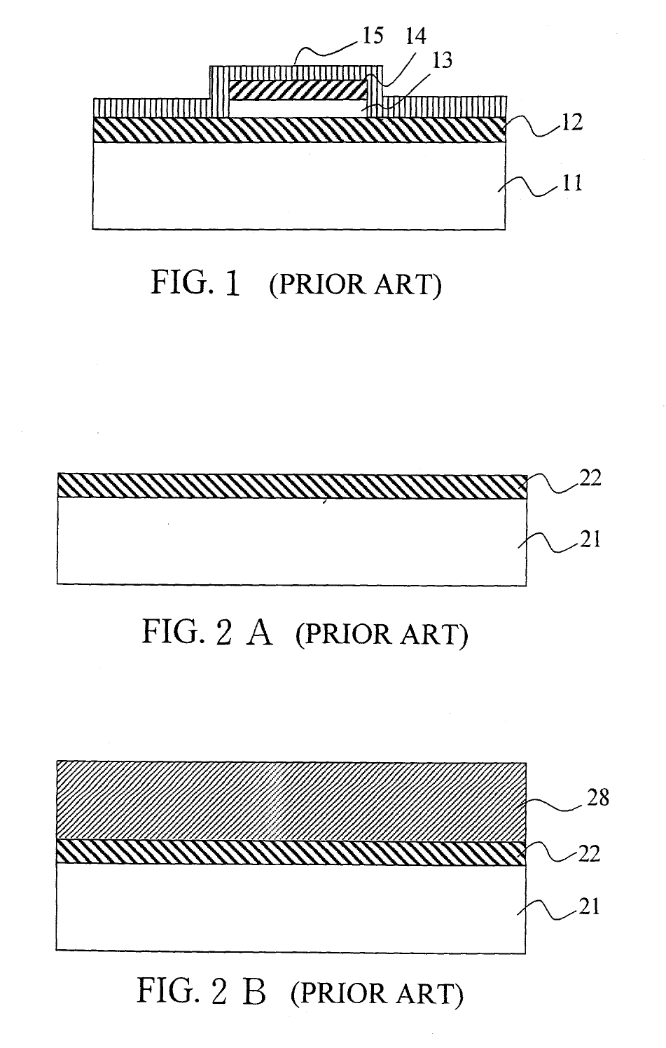

FIGS. 2A to 2G shows the manufacturing process of another conventional EL display device;

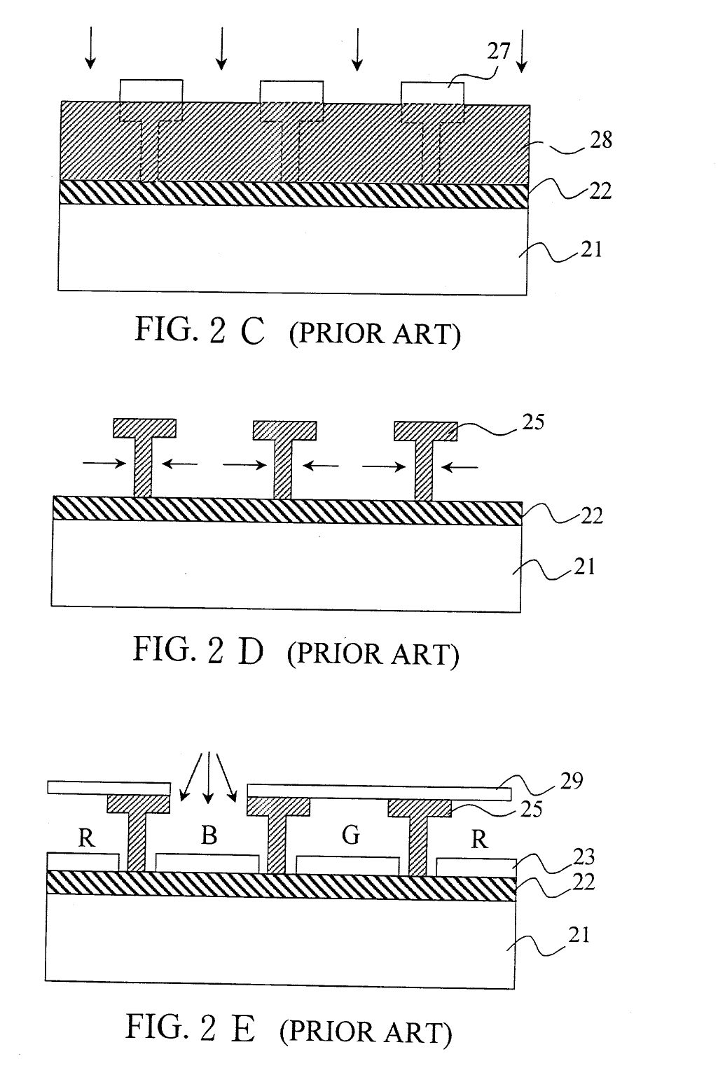

FIGS. 3A to 3F show the cross section view of each processing step according to a preferred embodiment of the present invention

FIG. 4A shows the cross section view of step 4 according to another preferred embodiment of the invention;

FIG. 4B shows the cross section view of the finished device according to the embodiment shown in FIG. 4A:

FIG. 5 shows the cross section view of organic electroluminescent device according to still another preferred embodiment of the invention;

FIG. 6 shows the cross section view of organic electroluminescent device according to still another preferred embodiment of the invention;

FIGS. 7A to 7E show the cross section view of each processing step according to still another preferred embodiment of the present invention;

FIG. 8 shows the cross section view of an organic electroluminescent device according to still another preferred embodiment of the invention ; and

FIG. 9 shows the cross section view of an organic electroluminescent device according to still another preferred embodiment of the invention.

### DETAIL DESCRIPTION OF PREFERRED EMBODIMENT

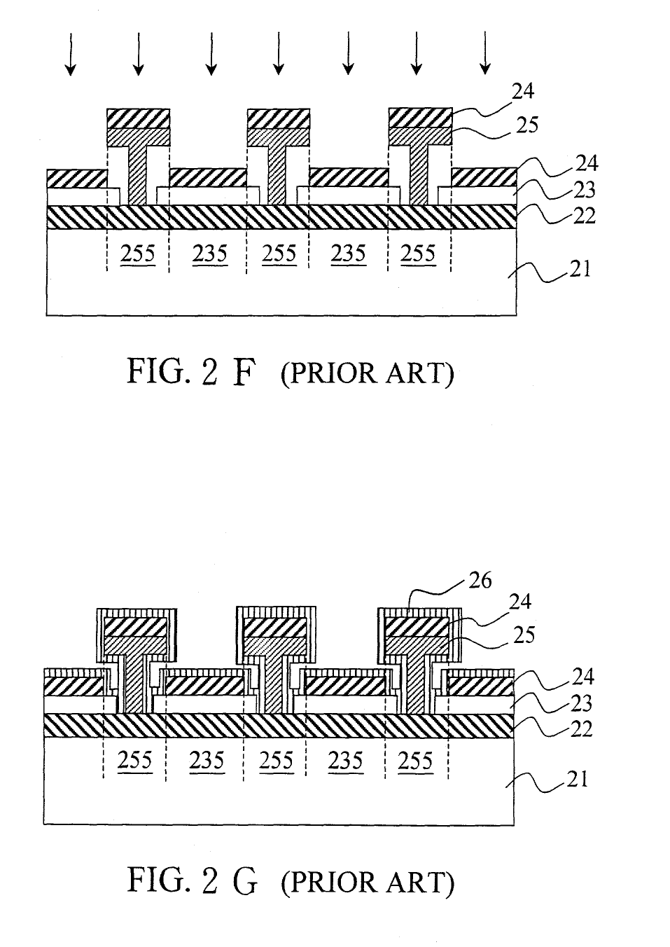

FIGS. 3A to 3F show the cross section view of each processing step according to a preferred embodiment of the present invention.

Step 1: as shown in FIG. 3A, forming a first electrode 32 on a substrate 31 wherein the substrate 31 can be a glass substrate and the first electrode 32 is a transparent electrode such as ITO;

Step 2: as shown in FIG. 3B, forming a plurality of contact windows on predetermined positions of the first electrode 32 by lithography method such as optical, e-beam, X-ray or ion beam lithography and mask 37;

Step 3: as shown in FIG. 3C, forming a plurality of trenches 35 penetrating through the first electrode 32 and penetrating into the substrate 31, forming an expected light emitting region 38 between two adjacent trenches 35;

Step 4: as shown in FIG. 3D, forming a plurality of organic layers 33 each emitting red (R), green (G) or blue (B) light by selectively evaporating on the first electrode 32 with the shadow mask 39, each organic layer 33 having at least one organic emitting layer (not shown);

Step 5: as shown in FIG. 3E, forming a second electrode 34 corresponding to the first electrode 32 on each organic layer 33 to conduct current through the organic layer 33 for emitting light ; and

Step 6: as shown in FIG. 3F, forming an insulating passivation layer 36 covering the first electrode 32, the organic layer 33 and the second electrode 34, the insulating passivation layer 36 being made of metal material feasible for processing in vacuum condition.

By above mentioned method, a full color organic electroluminescent device without an interlayer insulating layer is manufactured. The process is simplified. Moreover, the depth of the trench 35 can be controlled such that the organic layer 335 and the second electrode 345 formed by evaporation over the trench 35 are lower than the first electrode 32 on the expected light emitting region 38. Therefore, the trench 35 can provide necessary isolation between the first electrode 32 and the second electrode 345. Moreover, a vertical evaporation is feasible such that the organic layer 335 and the second electrode 345 can be formed with better alignment and fine pattern. The problem of short circuit occurred in oblique evaporation is prevented.

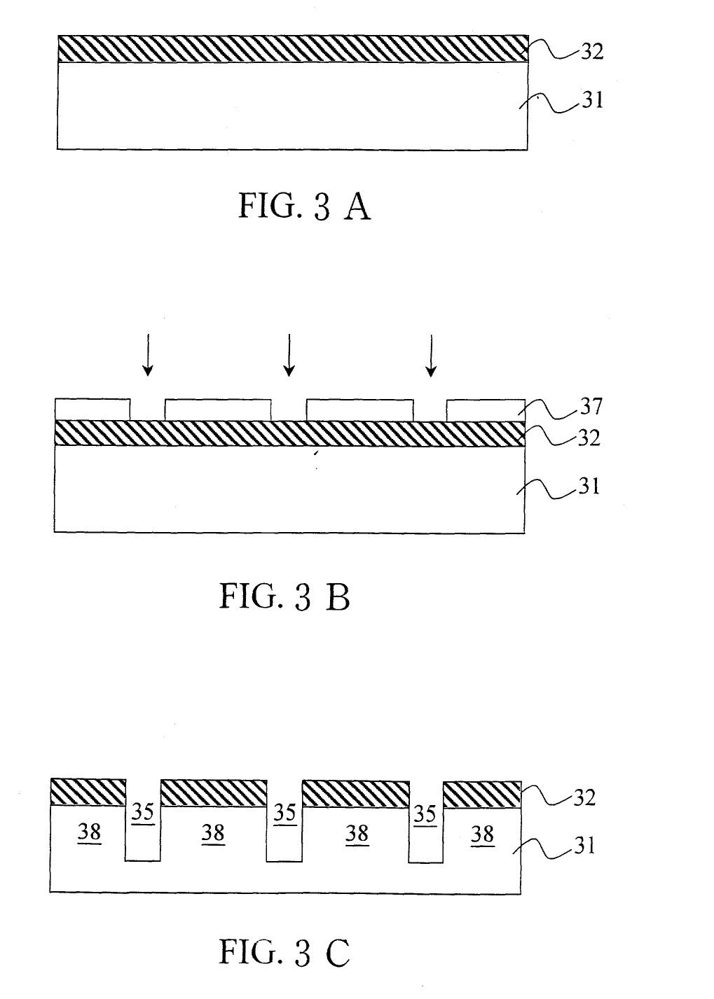

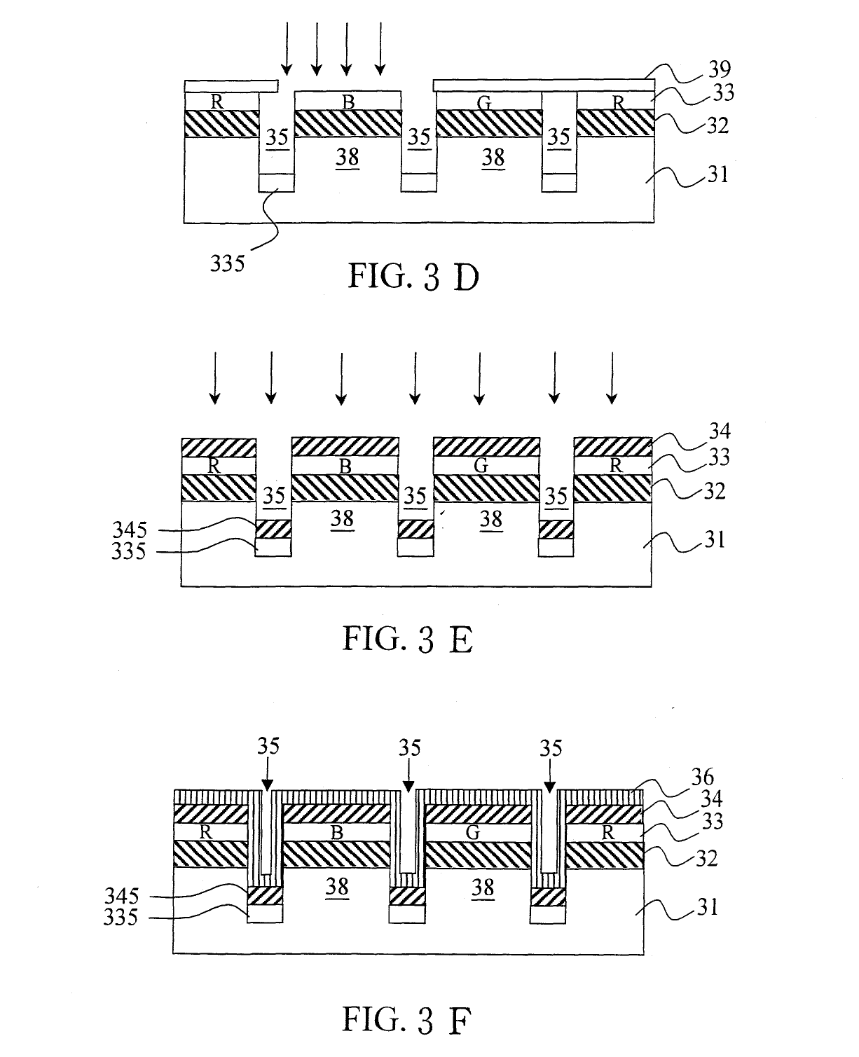

FIG. 4A shows the cross section view of step 4 according to another preferred embodiment of the invention. As shown in this figure, an auxiliary oblique evaporation process is used in conjunction with the primary vertical evaporation process to form a lateral passivation layer 333 on the lateral side of the organic layer 33 and cover the lateral region of the first electrode 32. The short circuit between the first electrode 32 and the second electrode 34 is prevented, as shown in FIG. 4B.

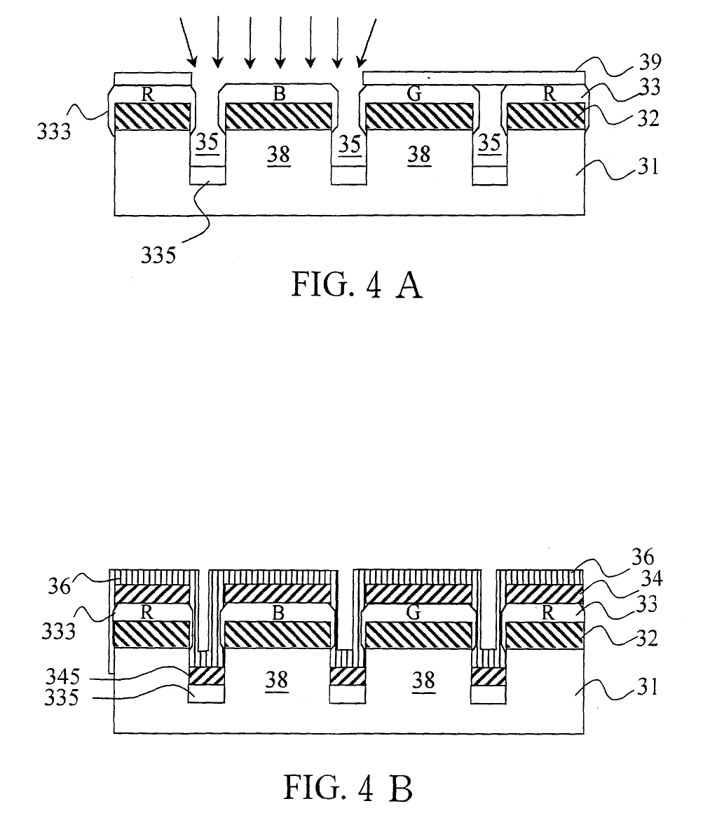

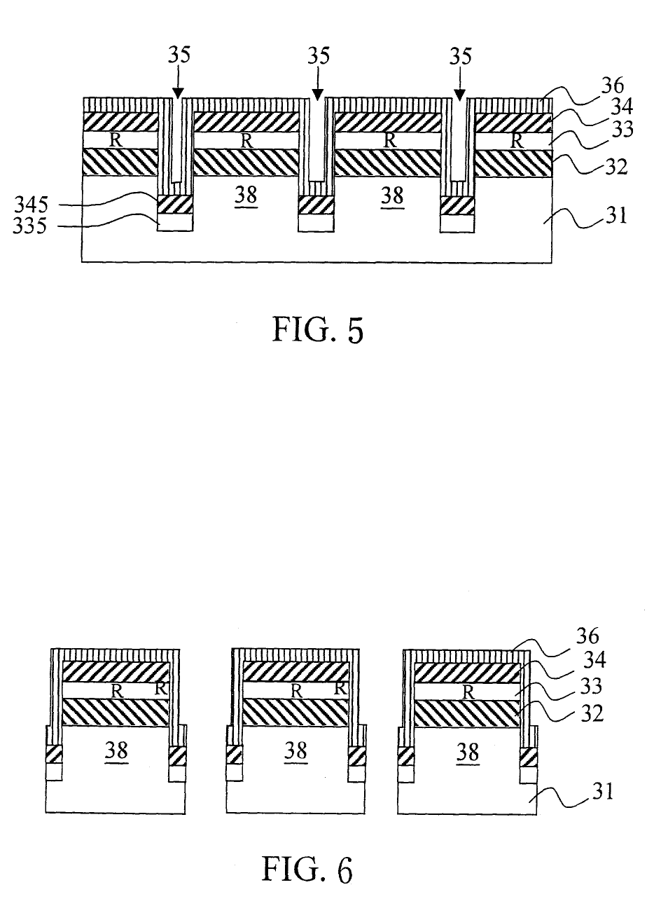

FIG. 5 shows the cross section view of organic electroluminescent device according to still another preferred embodiment of the invention. In this embodiment, a plurality organic layers 33 emitting monochromatic color are formed, for example, red color. The resulting structure is then singularized to individual unit as shown in FIG. 6.

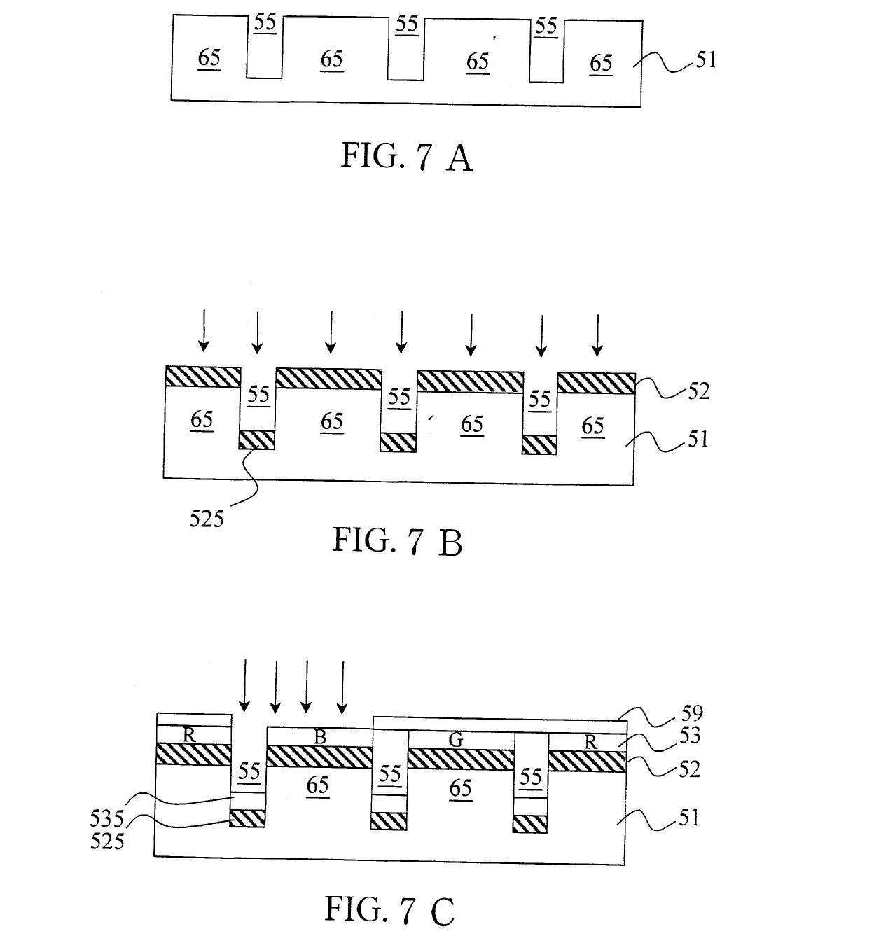

FIGS. 7A to 7E show the cross section view of each processing step according to still another preferred embodiment of the present invention.

Step 1: as shown in FIG. 7A, before forming first electrode on substrate 51, forming a plurality of trenches 55 on the substrate 51 by etching, forming an expected light emitting region 65 between two adjacent trenches 55;

Step 2: as shown in FIG. 7B, forming a first electrode 52 and 525 on the expected light emitting region 65 and trench 55, respectively;

Step 3: as shown in FIG. 7C, forming a plurality of organic layers 53, 535 each emitting red (R), green (G) or blue (B) light by selectively evaporating on the first electrode 52, 525 with the shadow mask 59, respectively;

Step 4: as shown in FIG. 7D, forming a second electrode 54, 545 on each organic layer 53, 535; and

Step 5: as shown in FIG. 7E, forming an insulating passivation layer 56 covering the first electrode 52, the organic layer 53 and the second electrode 54, the insulating passivation layer 56 being made of metal material feasible for processing in vacuum condition.

In this embodiment, a first electrode 525, an organic layer 535 and a second electrode 545 are formed within the trench 55. Therefore, the organic layer 535 in the trench 55 emits light when current passes therethrough. Therefore, the light-emitting area is enlarged. The dead angle of light emitting caused by the interlayer insulating layer is prevented. Moreover, similar to the previous embodiment, the depth of the trench 55 can be controlled such that the second electrode 545 formed by evaporation over the trench 55 is lower than the first electrode 52 on the expected light emitting region 65. Therefore, the trench 55 can provide necessary isolation between the first electrode and the second electrode.

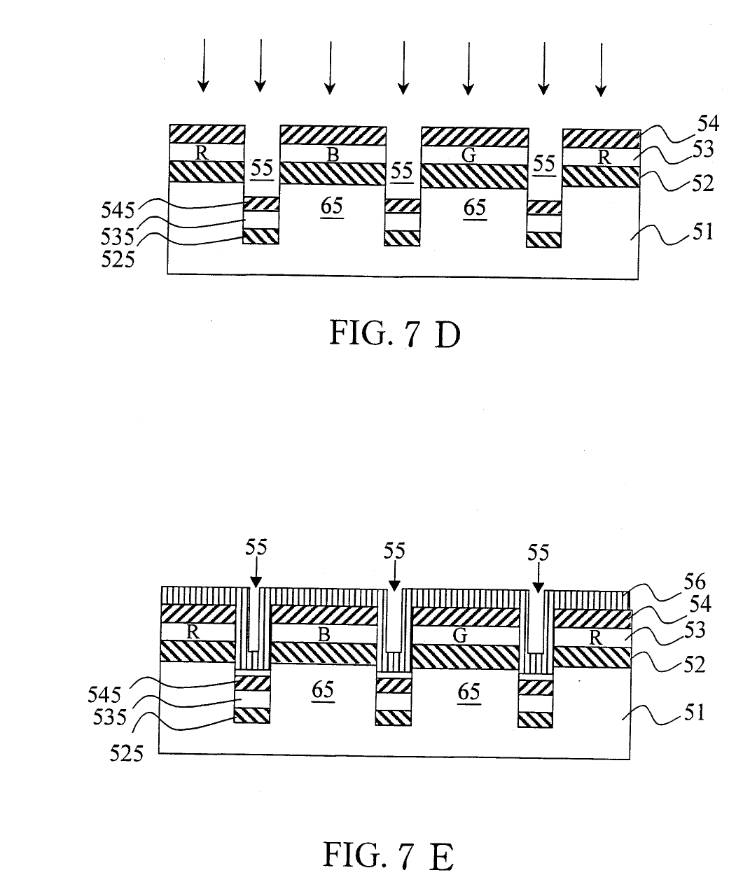

FIG. 8 shows the cross section view of an organic electroluminescent device according to still another preferred embodiment of the invention. As shown in this figure, the width of the trench 55 is the same as that of the expected light emitting region 65 such that the light emitted from the structure comprising the first electrode 525, the organic layer 535 and the second electrode 545 is compatible to the light emitted from the organic layer 53 of the expected light emitting region 65. Therefore, the light emitting efficiency is enhanced.

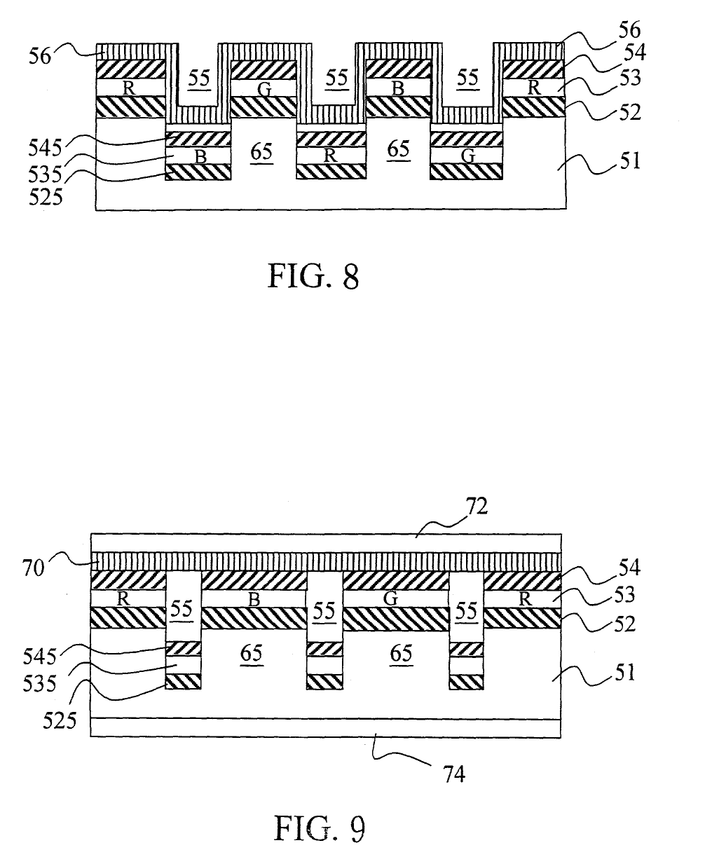

FIG. 9 shows the cross section view of an organic electroluminescent device according to still another preferred embodiment of the invention. As shown in this figure, a protecting film 70, rather than the insulating passivation layer 56 is used to cover the second electrode 54 to isolate the organic layer 53. Because the substrate 51 and the first electrode 52 are made of transparent materials, the light is emitted from the organic layer 53 and transmitted through the substrate 51 and the first electrode 52. Therefore, a reflective film 72 is provided on top of the protecting film 70 (or the insulating passivation layer 56) to enhance the illuminance efficiency.

Moreover, when the second electrode 54, the organic layer 53 and protecting film 70 (or the insulating passivation layer 56) are made of transparent materials, the light emitted from the organic layer 53 is transmitted through the second electrode 54 and protecting film 70 (or the insulating passivation layer 56). In this situation, the substrate 51 and the first electrode 52 can be made of non-transparent materials. A reflective film 74 is provided below the substrate 51 when the substrate 51 is made of non-transparent materials.

Although the present invention has been described with reference to the preferred embodiment thereof, it will be understood that the invention is not limited to the details thereof. Various substitutions and modifications have suggested in the foregoing description, and other will occur to those of ordinary skill in the art. Therefore, all such substitutions and modifications are intended to be embraced within the scope of the invention as defined in the appended claims.

I claim:

1. An organic electroluminescent device comprising
a substrate, a plurality of trenches formed by etching on predetermined positions of said substrate, a plurality of expected light emitting regions each formed between two adjacent trenches;
a first electrode formed on each said expected light emitting region;
a plurality of organic layers each formed on said first electrode; and
a plurality of second electrodes each formed on said organic layer.

2. The organic electroluminescent device as in claim 1, wherein the depth of said trench is below said first electrode on said expected light emitting region.

3. The organic electroluminescent device as in claim 1, further comprising an insulating passivation layer covering on said first electrode, said organic layer and said second electrode.

4. The organic electroluminescent device as in claim 1, further comprising a protective film formed on said second electrode.

5. The organic electroluminescent device as in claim 4, further comprising a reflective film formed upon said protective film.

6. The organic electroluminescent device as in claim 1, further comprising a reflective film formed below said substrate.

7. The organic electroluminescent device as in claim 1, wherein plurality of organic layers comprise organic layers emitting red, green and blue light.

8. The organic electroluminescent device as in claim 1, wherein plurality of organic layers are made of material emitting light of the same color.

9. The organic electroluminescent device as in claim 1, further comprising a lateral passivation layer covering on the lateral region of said first electrode.

10. The organic electroluminescent device as in claim 1, wherein the width of said trench is same as the width of said expected light emitting regions.

11. The organic electroluminescent device as in claim 10, wherein said first electrode, said organic layer and said second electrode are formed within said trench.

12. The organic electroluminescent device as in claim 1, wherein said substrate be sliced along said trenches to singularize the resulting structure into a plurality of organic electroluminescent devices emitting monochromatic light.

13. A method for making an organic electroluminescent device comprising the steps of:
a. forming a first electrode on a substrate;
b. forming a plurality of trenches penetrating through said first electrode and penetrating into said substrate by lithography process on said first electrode, forming an expected light emitting region between two adjacent trenches;
c. forming a plurality of organic layers each formed on one said first electrode by selectively evaporation with a shadow mask; and
d. forming a second electrode on one said organic layer.

14. The method for making an organic electroluminescent device as in claim 13, further comprising the steps after said step d: forming an insulating passivation layer covering said first electrode, said organic layer and said second electrode.

15. The method for making an organic electroluminescent device as in claim 13, further comprising the steps after said step d: slicing said substrate along said trenches to singularize the resulting structure into a plurality of organic electroluminescent devices emitting monochromatic light.

16. The method for making an organic electroluminescent device as in claim 13, further comprising the steps after said step d: forming a protective film on said second electrode.

17. The method for making an organic electroluminescent device as in claim 13, further comprising the step after the step d: forming a reflective film below said substrate.

18. The method for making an organic electroluminescent device as in claim 13, further comprising the step after the step c: forming a lateral passivation layer on the lateral side of said organic layer and cover the lateral region of said first electrode by an auxiliary oblique evaporation process.

19. A method for making an organic electroluminescent device comprising the steps of a. forming a plurality of trenches penetrating into a substrate by lithography process, forming an expected light emitting region between two adjacent trenches;
b. forming a plurality of first electrodes each positioned upon said trench and said expected light emitting region;
C. forming a plurality of organic layers each formed on one said first electrode by selectively evaporation with a shadow mask ; and
d. forming a second electrode on one said organic layer.

20. The method for making organic electroluminescent device as in claim 19, further comprising the steps after said step d: forming an insulating passivation layer covering said first electrode, said organic layer and said second electrode.

21. The method for making an organic electroluminescent device as in claim 19, further comprising the steps after said step d: slicing said substrate along said trenches to singularize the resulting structure into a plurality of organic electroluminescent devices emitting monochromatic light.

22. The method for making an organic electroluminescent device as in claim 19, further comprising the steps after said step d: forming a protective film on said second electrode.

23. The method for making an organic electroluminescent device as in claim 19, wherein the width of said trench formed in step a is the same as the width of said expected light emitting region.
